(19) United States
(12) Patent Application Publication
(10) Pub. No.: US 2026/0235678 A1
(43) Pub. Date: Aug. 13, 2026

(54) Intermittent Ground Fault Detection For Stators in High-Impedance Grounded Generators

(71) Applicant: WiSys Technology Foundation, Inc., Madison, WI (US)

(72) Inventor: Nader SAFARI-SHAD, Platteville, WI (US)

(21) Appl. No.: 19/156,612

(22) PCT Filed: Feb. 23, 2024
(86) PCT No.: PCT/US2024/017048

§ 371 Date: Aug. 14, 2025

Related U.S. Application Data
(60) Provisional application No. 63/486,552, filed on Feb. 23, 2023.

(51) Int. Cl. G01R 31/34; G01R 19/00; G01R 19/165; H02K 11/27

(52) U.S. Cl. CPC G01R 31/343; G01R 19/0007; G01R 19/0092; G01R 19/16547; H02K 11/27

(57) ABSTRACT

An intermittent stator ground fault detection system employs a subharmonic injection current and monitors subharmonics above and below the generator frequency and excluding the subharmonic injection current frequency to sensitively detect intermittent stator ground faults.

### CROSS REFERENCE TO RELATED APPLICATION

The present application claims the benefit of U.S. provisional 63/486,552 filed Feb. 23, 2023, and hereby incorporated by reference.

### BACKGROUND OF THE INVENTION

The present invention relates generally to devices for protecting electrical generators from ground faults and in particular to a device providing improved detection of intermittent ground faults in high-impedance grounded generators.

Electrical generators may provide for a set of stationary electrical coils in a stator that generate electricity by interaction with a magnetic field of a rotating rotor. For generators above 20 MVA, a neutral point in the stator coil connections may be connected to ground to limit transient overvoltage stress on the generator stator insulation and to minimize current flow through the stator coil during internal ground faults. This grounding can be directly through a resistor or indirectly through a resistor coupled by a transformer providing a reflected impedance of that resistance.

A number of techniques exist to detect stator ground faults by monitoring the current through this grounding connection. Common such systems include schemes 59N, 27TN, 59THD, and 64S following the ANSI device numbering convention described in ANSI/IEEE Standard C37.2 Standard for Electrical Power System Device Function Numbers, Acronyms, and Contact Designations. The IEEE C37.101 standard covers all the stator protective schemes. The above referenced standards, as of the date of the present application, are hereby incorporated by reference. Both 59N and 27TN use the voltage across the grounding resistor. 59N is an overvoltage scheme on the 50/60 Hz component of VN while 27TN is an undervoltage scheme on the 150/180 Hz component of VN. 59THD is the voltage differential scheme using the third harmonic component of VN and its corresponding voltage V_{T} at the terminal of the machine. There are several different types of 64S schemes based on a subharmonic current or both current and voltage.

Intermittent ground faults (IGF), also known as arcing faults, can occur in a generator due to dirty insulators or broken strands in generator stator windings. When left uncorrected, the high intermittent transient current caused by intermittent faults can damage the stator insulation and burn or melt stator iron armatures, and for that reason it is important to detect such intermittent faults at an early stage.

Current systems for ground fault detection may not adequately detect intermittent ground faults.

### SUMMARY OF THE INVENTION

The present invention provides an improved technique for detecting intermittent stator ground faults that can be readily integrated into higher impedance grounded generators using available neutral grounding current. The necessary circuitry needed for the invention, including the circuitry for subharmonic injection, is compatible with circuitry currently used in the 64S scheme, simplifying the adoption of this approach. The present invention may also provide a testing apparatus for the resulting ground fault detector.

In one embodiment, the invention provides an intermittent ground fault detector for electrical generators operating at a generator frequency and having a current injector injecting current into stator windings of the electrical generator at a subharmonic frequency of the generator frequency. A current monitor monitors a first current in at least one stator winding above or below the generator frequency, excluding the subharmonic frequency and generator frequency, and compares this first current to a baseline value based on a second current at the subharmonic frequency. A threshold detector triggers at least one of an alarm or a trip signal based on the comparison of the first current to the second current.

It is thus a feature of at least one embodiment of the invention to provide an improved method of detecting stator intermittent ground faults (IGF) not currently addressed in existing detection systems.

The threshold detector may trigger the alarm signal based on the first current being greater than the second current signal by a first predetermined amount for a first predetermined time interval.

It is thus a feature of at least one embodiment of the invention to provide two levels of detection suitable for both an alarm which does not disable the generator capacity, and tripping a circuit breaker to protect the generator.

The current monitor may connect to a neutral of the electrical generator to measure current between the neutral and ground. In some cases, the current monitor may measure current on a secondary of a transformer whose primary is connected between a neutral of the generator and ground, the secondary receiving current from the current injector.

It is thus a feature of at least one embodiment of the invention to provide a protection system generally compatible with existing ground current monitoring circuits.

The current monitor may provide a notch filter at the generator frequency and a summing junction subtracting the subharmonic frequency to create the signal indicating the current in at least one stator winding above and below the generator frequency excluding the subharmonic frequency and the generator frequency.

It is thus a feature of at least one embodiment of the invention to provide for a robust method of suppressing the dominant generator and sub harmonic frequencies.

These particular objects and advantages may apply to only some embodiments falling within the claims and thus do not define the scope of the invention.

### BRIEF DESCRIPTION OF THE DRAWINGS

FIG. 1 is a schematic representation of a generator showing the protection circuit of the present invention monitoring an impedance ground path from the generator;

FIG. 2 is a detailed block diagram of the protection circuit of FIG. 1 showing filtration and further processing of the monitored injection current to create an alarm and trip signal;

FIG. 3 is a simplified diagram of the injection current and the drive alarm and trip signals; and

FIG. 4 is a schematic representation of a device for simulating intermittent ground faults useful for the validating the protection circuit of FIGS. 1-3

### DETAILED DESCRIPTION OF THE PREFERRED EMBODIMENT

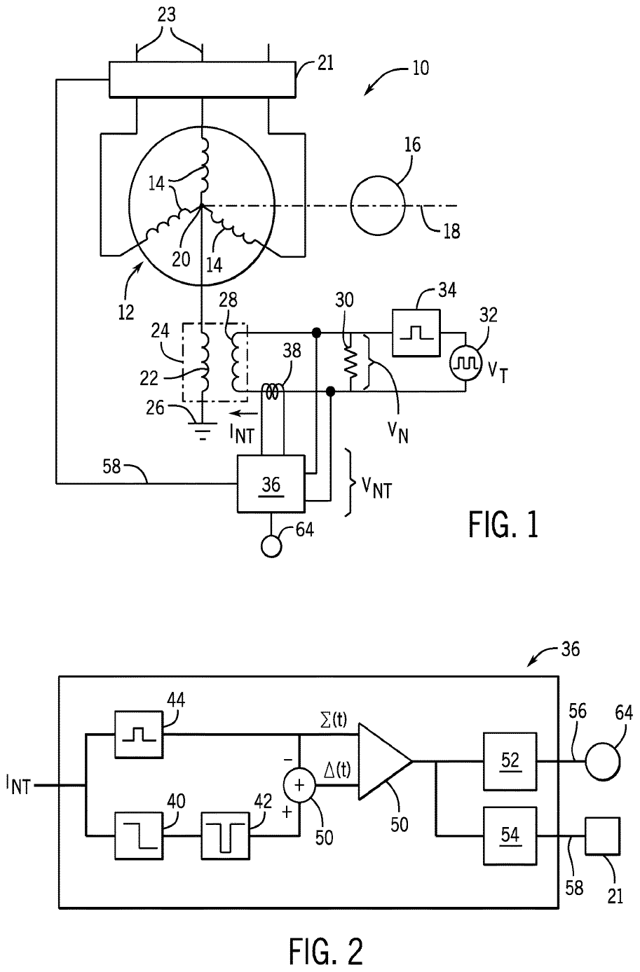

Referring now to FIG. 1, a generator system 10 may provide for a generator 12 having multiple stator windings 14 held stationary with respect to a rotating rotor 16 rotating about a rotor axis 18. The stator windings 14 may be connected in a so-called Y-configuration at a neutral point 20 and may have their other ends connected through a circuit breaker 21 with outlet terminals 23, for example, for outputting electrical power from the generator system 10.

The neutral point 20 of the generator 12 may be connected through a primary winding 22 of a transformer 24 to ground 26. The secondary winding 28 of the transformer is shunted by a resistor 30 providing controlled grounding of the neutral point 20 according to standard practice. The generator will have a typical operating frequency, termed the generator frequency which, in this example, will be 60 Hz but need not be so limited.

A subharmonic injection current I_{NT} is produced by an oscillator 32, for example, being a square wave generator having a voltage V_{T} running at 20 Hz for a 60 Hz generator. The voltage from the square wave generator is wave shaped to a sine wave by a bandpass filter 34 with a center frequency of 20 Hz and applied across the resistor to provide a voltage VN to approximate a narrowband sine wave. The injection current I_{NT} is conducted through the transformer 24 to the windings 14 of the generator 12 and is also measured by a ground fault detection circuit 36 using current transformer 38. The current transformer 38 will have a bandwidth of at least 6 kHz and more typically will be able to measure currents from microamps to 20 kA at frequencies ranging from 0.5 Hz to 500 MHz. The ground fault detection circuit 36 may also measure the voltage VN across resistor 30.

Referring now to FIG. 2, the ground fault detection circuit 36 receives a measurement of the injection current I_{NT} at a series-connected low-pass filter 40 and notch filter 42, each of which may be second-order filters, with the low-pass filter having a cutoff frequency of approximately 6 kHz and the notch filter 42 having a stop band centered at 60 Hz, being the operating frequency of generator. Optionally a third notch filter (not shown) can be provided in series with filters 40 and 42 to provide a narrow stop band around 150/180 Hz to block third harmonics of the operating frequency of 50/60 Hz.

The ground fault detection circuit 36 further receives the measurement of the current I_{NT} at a bandpass filter for example, a fourth-order bandpass filter 44 with a center frequency of 20 Hz corresponding to the frequency of the oscillator 32.

At summing block 46, the output of the filter 44 is subtracted from the output of the series filters 40 and 42 to provide a signal Δ(t) while the output of the filter 44 alone provides a signal ε(t). These two signals are provided to a comparator 50 having an output received by an alarm detector 52 and a trip detector 54 to create an alarm output 56 if:

$$\vert Δ ( t ) \vert > {β}_{1} \vert ε ( t ) \vert \qquad ( 1 )$$

### For a First Predetermined Number of Samples j, and to Create a Trip Output 58 Signal if:

$$\vert Δ ( t ) \vert > {β}_{2} \vert ε ( t ) \vert \qquad ( 2 )$$

for a second predetermined number of samples k.

In one non-limiting example, β₁ and β₂ may each be greater than one, for example, 1.1, and the first predetermined number of samples j may be 25, and the second predetermined number of samples k may be 50 at a sampling frequency equal to the generator frequency. These values are set for a particular generator so that the trip logic asserts in about one second and will generally be more than a fifth of the second for condition (1) and more than one-half second for condition (2). Generally conditions (1) and (2) will be sampling times of greater than 10 samples in less than 200 samples. If the sampling times of conditions (1) and (2) cease for a period of five sampling times after 15 samples have been registered, accumulated times are reset.

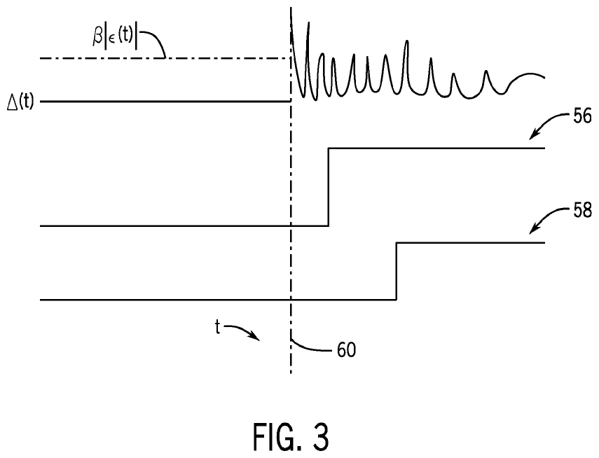

Referring now to FIG. 3, at a time 60 of an intermittent fault, the peak value of A (t) above restraint values of β_{1,2}|ε(t)| triggers an alarm output 56, first per condition (1) and subsequently a trip signal 58 per condition (2).

Referring now to FIG. 1 the alarm output 56 may be provided to a signaling device 64, for example, a light, siren, or remote communication device, and the trip signal 58 may be provided to the circuit breaker 21 to disconnect the generator 12 from electrical connection with its downstream circuitry.

The above-described circuitry may be implemented with discrete components or by means of a computer or digital signal processor measuring the current I_{NT} with an analog-to-digital converter converting the measurement to a digital signal. It will be appreciated from the above description that, for generators operating at frequencies other than 60 Hz, the above values of the various filters may be appropriately scaled and that other parameters may be adjusted empirically for particular generators.

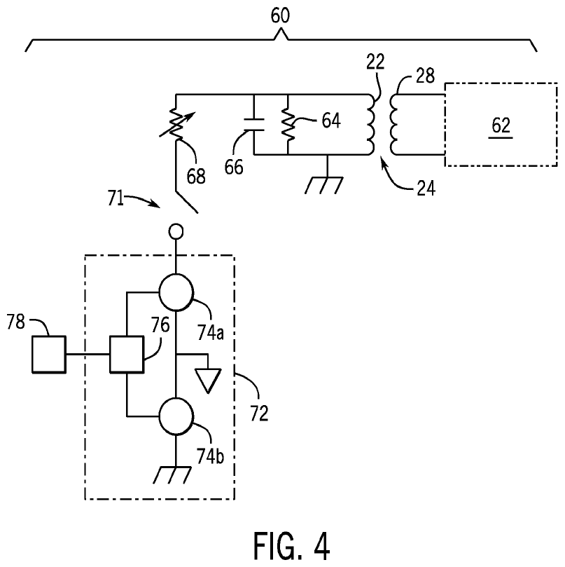

Referring now to FIG. 4, a test circuit 60 may be constructed and used to validate operation of the intermittent ground fault detector 62 described above. In use, the intermittent ground fault detector 62 may connect to the secondary winding 28 of transformer 24, in this case, being part of the test circuit 60. The primary winding 22 of the transformer 24 may be shunted by a resistor 64 and a capacitor 66. The resistor 64 is selected to represent the insulation of a healthy stator of the type of generator to be simulated, typically on the order of 100 k ohms whereas the capacitor 66 will be selected to represents the total capacitance to ground of the simulated generator windings, iso-phase, bus work and delta-connected stator windings of the generator step-up transformer. In some cases, capacitor 66 will be on the order of 0.78 μF, or may be variably switched between 0.5 μF and 1.0 μF.

A variable fault resistance 68, for example, implemented using a decade box, may provide for a variation in fault resistances from 0 to 10 k ohms for various testing regimes. This variable fault resistor 68 will be, as below, intermittently shorted to ground provide a fault-like shorting of the injection current from the ground fault detector 62 to ground as might be caused by arcing.

A test sequence may be activated by closing a knife switch 71 connecting one side of the fault resistance 68 to a four-quadrant switch 72. This connection draws a fault current through the primary winding 28 by means of switching of the four-quadrant switch 72 which provides a duty cycle and frequency controllable intermittent path to ground. The four-quadrant switch 72 may employ series connected MOSFETs 74a and 74b with internal flyback diodes alternately switched by a driver integrated circuit 76 according to a duty cycle modulated square wave from fault signal generator 78.

The fault signal generator 78, may, for example, be a microprocessor executing a stored program allowing user settings of frequency and duty cycle of the duty cycle modulated square wave. Typically, the duty cycle modulated square wave will be at a multiple (for example, 2) of the generator frequency. For example, the duty cycle modulated square wave may have a fundamental frequency of 120 Hz for a generator being simulated having a generator frequency of 60 Hz. In this way, the duty cycle modulated square wave may simulate intermittent faults that occur from the peak generator voltage to its zero crossing caused by arcing and the like and occurring twice per generator frequency cycle. The duty cycle of this square wave may be adjusted according to an intended simulated arc duration in the intermittent fault thereby controlling the four-quadrant switch 72 appropriately. In some examples, the duty cycle may be adjusted for different testing regimes between 5% and 50% in steps of 5%.

The testing may be terminated by opening switch 71. In some embodiments, an additional switch (or switch pole) may be provided to produce a continuous rather than intermittent fault by simply shorting the fault resistor 68 the ground.

By employing this testing system, the need for an actual generator producing intermittent faults is avoided and the operation of the ground fault detectors 62 may be evaluated by generating types of fault signals for a variety of different types of generators and determining whether the ground fault detector 62 operates properly to detect those faults.

Certain terminology is used herein for purposes of reference only, and thus is not intended to be limiting. For example, terms such as “upper”, “lower”, “above”, and “below” refer to directions in the drawings to which reference is made. Terms such as “front”, “back”, “rear”, “bottom”, and “side”, describe the orientation of portions of the component within a consistent but arbitrary frame of reference which is made clear by reference to the text and the associated drawings describing the component under discussion. Such terminology may include the words specifically mentioned above, derivatives thereof, and words of similar import. Similarly, the terms “first”, “second” and other such numerical terms referring to structures do not imply a sequence or order unless clearly indicated by the context.

When introducing elements or features of the present disclosure and the exemplary embodiments, the articles “a”, “an”, “the” and “said” are intended to mean that there are one or more of such elements or features. The terms “comprising”, “including” and “having” are intended to be inclusive and mean that there may be additional elements or features other than those specifically noted. It is further to be understood that the method steps, processes, and operations described herein are not to be construed as necessarily requiring their performance in the particular order discussed or illustrated, unless specifically identified as an order of performance. It is also to be understood that additional or alternative steps may be employed.

References to “a microprocessor” and “a processor” or “the microprocessor” and “the processor,” can be understood to include one or more microprocessors that can communicate in a stand-alone and/or a distributed environment(s), and can thus be configured to communicate via wired or wireless communications with other processors, where such one or more processor can be configured to operate on one or more processor-controlled devices that can be similar or different devices. Furthermore, references to memory, unless otherwise specified, can include one or more processor-readable and accessible memory elements and/or components that can be internal to the processor-controlled device, external to the processor-controlled device, and can be accessed via a wired or wireless network.

It is specifically intended that the present invention not be limited to the embodiments and illustrations contained herein and the claims should be understood to include modified forms of those embodiments including portions of the embodiments and combinations of elements of different embodiments as come within the scope of the following claims. All of the publications described herein, including patents and non-patent publications, are hereby incorporated herein by reference in their entireties.

To aid the Patent Office and any readers of any patent issued on this application in interpreting the claims appended hereto, applicants wish to note that they do not intend any of the appended claims or claim elements to invoke 35 U.S.C. 112(f) unless the words “means for” or “step for” are explicitly used in the particular claim.

What we claim is:

1. An intermittent ground fault detector for electrical generators operating at a generator frequency and comprising:
a current injector injecting current into stator windings of the electrical generator at an injector frequency offset from the generator frequency;
a current monitor monitoring a first current in at least one stator winding above and below the generator frequency excluding the injector frequency and generator frequency and comparing this first current to a baseline value based on a second current at the injector frequency; and
a threshold detector triggering at least one of an alarm or a trip signal based on a comparison of the first current to the second current.

2. The intermittent ground fault detector of claim 1 wherein the threshold detector triggers the alarm signal based on the first current signal being greater than the second current signal by a first predetermined amount for a first predetermined time interval.

3. The intermittent ground fault detector of claim 2 wherein the first predetermined time interval is greater than ⅕ second.

4. The intermittent ground fault detector of claim 3 wherein the first predetermined amount is greater than 1.

5. The intermittent ground fault detector of claim 1 further including a circuit breaker controlling current to the windings and wherein the threshold detector triggers an alarm based on the first current being greater than the second current by the first predetermined amount for the first predetermined time and triggers the trip signal tripping the circuit breaker when the first current is greater than the second current by a second predetermined amount for a second predetermined time longer than the first predetermined time.

6. The intermittent ground fault detector of claim 5 wherein the first predetermined time interval is greater than ½ second.

7. The intermittent ground fault detector of claim 6 wherein the second predetermined amount is greater than 1.

8. The intermittent ground fault detector of claim 5 wherein the first and second predetermined times are greater than 10 cycles of the generator frequency and less than 200 cycles of the generator frequency.

9. The intermittent ground fault detector of claim 5 wherein the first and second predetermined times must be uninterrupted for no longer than a third predetermined time less than the first predetermined time.

10. The intermittent ground fault detector of claim 1 wherein the current monitor connects to a neutral of the electrical generator to measure current between the neutral and ground.

11. The intermittent ground fault detector of claim 10 wherein the current monitor measures current on a secondary of a transformer whose primary is connected between a neutral of the generator ground, the secondary receiving current from the current injector.

12. The intermittent ground fault detector of claim 1 wherein the current monitor provides a notch filter at the generator frequency and a summing junction subtracting the subharmonic frequency to measure the first current indicating the current in the at least one stator winding above and below the generator frequency excluding the subharmonic frequency and the generator frequency.

13. The intermittent ground fault detector of claim 1 wherein the current injector is shunted by a resistance.

14. The intermittent ground fault detector of claim 1 wherein the current injector is a square wave generator in series with a bandpass filter with a center frequency at the subharmonic.

15. The intermittent ground fault detector of claim 1 wherein the subharmonic is less than half the frequency of the generator.

16. The intermittent ground fault detector of claim 1 wherein the generator frequency is 60 Hz and the subharmonic frequency is 20 Hz.

17. An apparatus for testing an intermittent ground fault detector of a type having:
a current injector injecting current into stator windings of the electrical generator at a subharmonic an injector frequency offset from the generator frequency;
a current monitor monitoring a first current in at least one stator winding above and below the generator frequency excluding the subharmonic injector frequency and generator frequency and comparing this first current to a baseline value based on a second current at the subharmonic injector frequency; and
a threshold detector triggering at least one of an alarm or a trip signal based on a comparison of the first current to the second current;
the apparatus comprising:
a current transformer having a secondary for connecting to the ground fault detector and a primary providing a voltage source switchably shunted to ground at a controllable frequency and controllable duty cycle to simulate intermittent ground faults.

18. The apparatus of claim 17 further including a resistance and capacitance shunting the primary of the current transformer and having respective values representing stator insulation resistance and stator capacitive coupling.

19. The apparatus of claim 17 including a variable resistor positioned in the path of the shunted current to ground.
